(19) United States
(12) Patent Application Publication
(10) Pub. No.: US 2026/0105975 A1
(43) Pub. Date: Apr. 16, 2026

(54) DEEP LEARNING BASED ITERATIVE VOLTAGE THRESHOLD ESTIMATION FOR NAND FLASH MEMORY

(71) Applicant: SK hynix Inc., Gyeonggi-do (KR)

(72) Inventors: Fan ZHANG, San Jose, CA (US); Haobo WANG, San Jose, CA (US)

(21) Appl. No.: 18/917,954

(22) Filed: Oct. 16, 2024

(51) Int. Cl. G11C 16/34; G11C 16/26

(52) U.S. Cl. CPC G11C 16/3404; G11C 16/26

(57) ABSTRACT

A memory system and associated method for calculating a voltage threshold for reading data from the memory system. The memory system including a memory device including multiple pages in a memory region and a controller coupled to the memory device. The controller is configured to: perform at least one read operation on the memory device including reading of the multiple pages in a memory region of the memory device to obtain program voltage state distributions across the multiple pages; generate a synthetic model of the program voltage state distributions of the memory device based on the at least one read operation; and calculate from the synthetic model at least one voltage threshold between two of the program voltage state distributions.

### BACKGROUND

### 1. Field

Embodiments of the present disclosure relate to a scheme for learning voltage threshold values in a memory system.

### 2. Description of the Related Art

The computer environment paradigm has shifted to ubiquitous computing systems that can be used anytime and anywhere. As a result, the use of portable electronic devices such as mobile phones, digital cameras, and notebook computers has rapidly increased. These portable electronic devices generally use a memory system having memory device(s), that is, data storage device(s). The data storage device is used as a main memory device or an auxiliary memory device of the portable electronic devices.

Memory systems using memory devices provide excellent stability, durability, high information access speed, and low power consumption, since they have no moving parts. Examples of memory systems having such advantages include universal serial bus (USB) memory devices, memory cards having various interfaces such as a universal flash storage (UFS), and solid state drives (SSDs). Memory systems may use various methods to determine voltage thresholds for data read operations.

### SUMMARY

In one aspect, there is provided a memory system including a memory device including multiple pages in a memory region and a controller coupled to the memory device. The controller is configured to: perform at least one read operation on the memory device including reading of the multiple pages in a memory region of the memory device to obtain program voltage state distributions across the multiple pages; generate a synthetic model of the program voltage state distributions of the memory device based on the at least one read operation; and calculate from the synthetic model at least one voltage threshold between two of the program voltage state distributions.

In another aspect, there is provided a method for calculating a voltage threshold for reading data from a memory system including a memory device having multiple pages in a memory region and a controller coupled to the memory device, the method comprising: performing at least one read operation on a memory device including reading of multiple pages in a memory region of the memory device to obtain program voltage state distributions across the multiple pages; generating a synthetic model of the program voltage state distributions of the memory device based on the at least one read operation; and calculating from the synthetic model at least one voltage threshold between two of the program voltage state distributions.

Additional aspects of the present invention will become apparent from the following description.

### BRIEF DESCRIPTION OF THE DRAWINGS

FIG. 1 is a block diagram illustrating a data processing system in accordance with one embodiment of the present invention.

FIG. 2 is a block diagram illustrating a memory system in accordance with another embodiment of the present invention.

FIG. 3 is a circuit diagram illustrating a memory block of a memory device in accordance with an embodiment of the present invention.

FIG. 4 is a diagram illustrating distributions of states for different types of cells of a memory device.

FIG. 5A is a diagram illustrating an example of Gray coding for a multi-level cell (MLC).

FIG. 5B is a diagram illustrating state distributions for pages of a multi-level cell (MLC).

FIG. 6A is a diagram illustrating an example of Gray coding for a triple-level cell (TLC).

FIG. 6B is a diagram illustrating state distributions for pages of a triple-level cell (TLC).

FIG. 7 illustrates an example of a deep neural network architecture for data storage performance optimization implemented based on some embodiments of the disclosed technology.

FIG. 8 illustrates an example configuration of a computational neural network including input neurons, hidden neurons, output neurons, and synapse layers.

FIG. 9 is a graph depicting the PV distributions of for a TLC near end of life (EOL).

FIG. 10 is a depiction of an iterative Vt estimation according to one embodiment of the present disclosure.

FIG. 11 is a diagram depicting the integration of various models into an iterative Vt estimation for an LSB page, in accordance with another embodiment of the present invention.

FIG. 12 is a diagram depicting a nested iterative Vt estimation, in accordance with another embodiment of the present invention

FIG. 13 is a flowchart illustrating a voltage threshold estimation operation in accordance with another embodiment of the present invention.

### DETAILED DESCRIPTION

Various embodiments are described below in more detail with reference to the accompanying drawings. The present invention may, however, be embodied in different forms and thus should not be construed as limited to the embodiments set forth herein. Rather, these embodiments are provided so that this disclosure is thorough and complete and fully conveys the scope of the present invention to those skilled in the art. Moreover, reference herein to “an embodiment,” “another embodiment,” “one embodiment,” or the like is not necessarily to only one embodiment, and different references to any such phrase are not necessarily to the same embodiment(s). The term “embodiments” as used herein does not necessarily refer to all embodiments. Throughout the disclosure, like reference numerals refer to like parts in the figures and embodiments of the present invention.

The invention can be implemented in numerous ways, including as a process; an apparatus; a system; a computer program product embodied on a computer-readable storage medium; and/or a processor, such as a processor suitable for executing instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being suitable for performing a task may be implemented as a general component that is temporarily configured to perform the task at a given time or a specific component that is manufactured to perform the task. As used herein, the term ‘processor’ or the like refers to one or more devices, circuits, and/or processing cores suitable for processing data, such as computer program instructions.

A detailed description of embodiments of the invention is provided below along with accompanying figures that illustrate aspects of the invention. The invention is described in connection with such embodiments, but the invention is not limited to any embodiment. The invention encompasses numerous alternatives, modifications and equivalents within the scope of the disclosure. Numerous specific details are set forth in the following description in order to provide a thorough understanding of the invention. These details are provided for the purpose of example; the invention may be practiced without some or all of these specific details. For clarity, technical material that is known in technical fields related to the invention has not been described in detail so that the invention is not unnecessarily obscured.

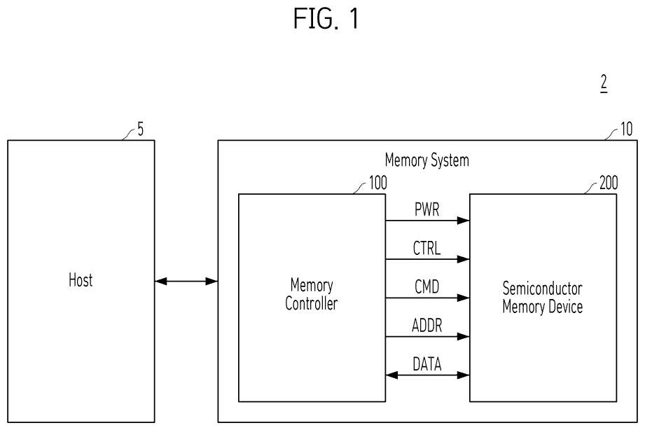

FIG. 1 is a block diagram illustrating a data processing system 2 in accordance with one embodiment of the present invention.

Referring FIG. 1, the data processing system 2 may include a host device 5 and a memory system 10. The memory system 10 may receive a request from the host device 5 and operate in response to the received request. For example, the memory system 10 may store data to be accessed by the host device 5.

The host device 5 may be implemented with any one of various kinds of electronic devices. In various embodiments, the host device 5 may include an electronic device such as a desktop computer, a workstation, a three-dimensional (3D) television, a smart television, a digital audio recorder, a digital audio player, a digital picture recorder, a digital picture player, and/or a digital video recorder and a digital video player. In various embodiments, the host device 5 may include a portable electronic device such as a mobile phone, a smart phone, an e-book, an MP3 player, a portable multimedia player (PMP), and/or a portable game player.

The memory system 10 may be implemented with any one of various kinds of storage devices such as a solid state drive (SSD) and a memory card. In various embodiments, the memory system 10 may be provided as one of various components in an electronic device such as for example one or more of a computer, an ultra-mobile personal computer (PC) (UMPC), a workstation, a net-book computer, a personal digital assistant (PDA), a portable computer, a web tablet PC, a wireless phone, a mobile phone, a smart phone, an e-book reader, a portable multimedia player (PMP), a portable game device, a navigation device, a black box, a digital camera, a digital multimedia broadcasting (DMB) player, a 3-dimensional television, a smart television, a digital audio recorder, a digital audio player, a digital picture recorder, a digital picture player, a digital video recorder, a digital video player, a storage device of a data center, a device capable of receiving and transmitting information in a wireless environment, a radio-frequency identification (RFID) device, as well as one of various electronic devices of a home network, one of various electronic devices of a computer network, one of electronic devices of a telematics network, or one of various components of a computing system.

The memory system 10 may include a memory controller 100 and a semiconductor memory device 200. The memory controller 100 may control overall operations of the semiconductor memory device 200.

The semiconductor memory device 200 may perform one or more erase, program, and read operations under the control of the memory controller 100. The semiconductor memory device 200 may receive a command CMD, an address ADDR and data DATA through input/output lines. The semiconductor memory device 200 may receive power PWR through a power line and a control signal CTRL through a control line. The control signal CTRL may include a command latch enable signal, an address latch enable signal, a chip enable signal, a write enable signal, a read enable signal, as well as other operational signals depending on design and configuration of the memory system 10.

The memory controller 100 and the semiconductor memory device 200 may be integrated in a single semiconductor device such as a solid state drive (SSD). The SSD may include a storage device for storing data therein. When the semiconductor memory system 10 is used in an SSD, operation speed of a host device (e.g., host device 5 of FIG. 1) coupled to the memory system 10 may remarkably improve.

The memory controller 100 and the semiconductor memory device 200 may be integrated in a single semiconductor device such as a memory card. For example, the memory controller 100 and the semiconductor memory device 200 may be so integrated to configure a personal computer (PC) card of personal computer memory card international association (PCMCIA), a compact flash (CF) card, a smart media (SM) card, a memory stick, a multimedia card (MMC), a reduced-size multimedia card (RS-MMC), a micro-size version of MMC (MMCmicro), a secure digital (SD) card, a mini secure digital (miniSD) card, a micro secure digital (microSD) card, a secure digital high capacity (SDHC), and/or a universal flash storage (UFS).

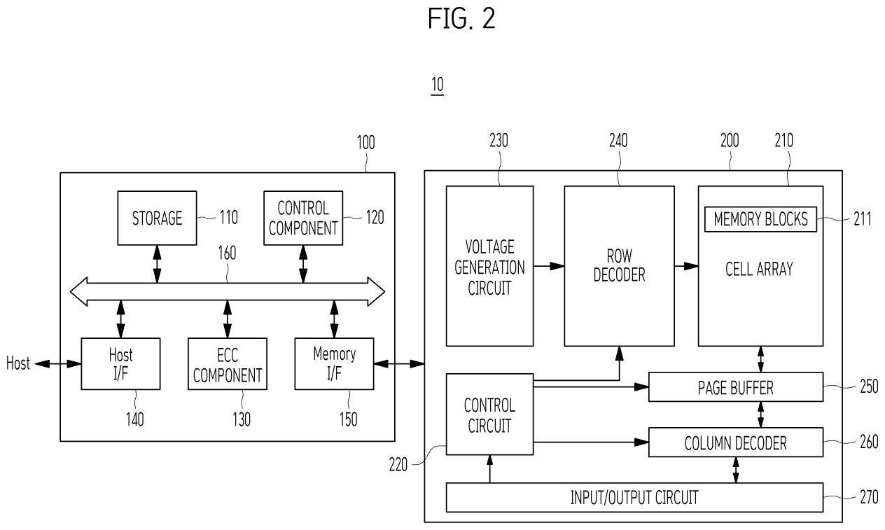

FIG. 2 is a block diagram illustrating a memory system in accordance with another embodiment of the present invention. For example, the memory system of FIG. 2 may depict the memory system 10 shown in FIG. 1.

Referring to FIG. 2, the memory system 10 may include a memory controller 100 and a semiconductor memory device 200. The memory system 10 may operate in response to a request from a host device (e.g., host device 5 of FIG. 1), and in particular, store data to be accessed by the host device.

The memory device 200 may store data to be accessed by the host device.

The memory device 200 may be implemented with a volatile memory device such as a dynamic random access memory (DRAM) and/or a static random access memory (SRAM) or a non-volatile memory device such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase change RAM (PRAM), a magnetoresistive RAM (MRAM), and/or a resistive RAM (RRAM).

The controller 100 may control storage of data in the memory device 200. For example, the controller 100 may control the memory device 200 in response to a request from the host device. The controller 100 may provide data read from the memory device 200 to the host device, and may store data provided from the host device into the memory device 200.

The controller 100 may include a storage 110, a control component 120, which may be implemented as a processor such as a central processing unit (CPU), an error correction code (ECC) component 130, a host interface (I/F) 140 and a memory interface (I/F) 150, which are coupled through a bus 160.

The storage 110 may serve as a working memory of the memory system 10 and the controller 100, and store data for driving the memory system 10 and the controller 100. When the controller 100 controls operations of the memory device 200, the storage 110 may store data used by the controller 100 and the memory device 200 for such operations as read, write, program and erase operations.

The storage 110 may be implemented with a volatile memory such as a static random access memory (SRAM) or a dynamic random access memory (DRAM). As described above, the storage 110 may store data used by the host device in the memory device 200 for the read and write operations. To store the data, the storage 110 may include a program memory, a data memory, a write buffer, a read buffer, a map buffer, and the like.

The control component 120 may control general operations of the memory system 10, and a write operation or a read operation for the memory device 200, in response to a write request or a read request from the host device. The control component 120 may drive firmware, which is referred to as a flash translation layer (FTL), to control general operations of the memory system 10. For example, the FTL may perform operations such as logical-to-physical (L2P) mapping, wear leveling, garbage collection, and/or bad block handling. The L2P mapping is known as logical block addressing (LBA).

The ECC component 130 may detect and correct errors in the data read from the memory device 200 during the read operation. The ECC component 130 may not correct error bits when the number of the error bits is greater than or equal to a threshold number of correctable error bits, and instead may output an error correction fail signal indicating failure in correcting the error bits.

In various embodiments, the ECC component 130 may perform an error correction operation based on a coded modulation such as a low density parity check (LDPC) code, a Bose-Chaudhuri-Hocquenghem (BCH) code, a turbo code, a turbo product code (TPC), a Reed-Solomon (RS) code, a convolution code, a recursive systematic code (RSC), a trellis-coded modulation (TCM), or a Block coded modulation (BCM). However, error correction is not limited to these techniques. As such, the ECC component 130 may include any and all circuits, systems or devices for suitable error correction operation.

The host interface 140 may communicate with the host device through one or more of various interface protocols such as a universal serial bus (USB), a multi-media card (MMC), a peripheral component interconnect express (PCI-e or PCIe), a small computer system interface (SCSI), a serial-attached SCSI (SAS), a serial advanced technology attachment (SATA), a parallel advanced technology attachment (PATA), an enhanced small disk interface (ESDI), and an integrated drive electronics (IDE).

The memory interface 150 may provide an interface between the controller 100 and the memory device 200 to allow the controller 100 to control the memory device 200 in response to a request from the host device. The memory interface 150 may generate control signals for the memory device 200 and process data under the control of the control component 120. When the memory device 200 is a flash memory such as a NAND flash memory, the memory interface 150 may generate control signals for the memory and process data under the control of the control component 120.

The memory device 200 may include a memory cell array 210, a control circuit 220, a voltage generation circuit 230, a row decoder 240, a page buffer 250, which may be in the form of an array of page buffers, a column decoder 260, and an input and output (input/output) circuit 270. The memory cell array 210 may include a plurality of memory blocks 211 which may store data. The voltage generation circuit 230, the row decoder 240, the page buffer array 250, the column decoder 260 and the input/output circuit 270 may form a peripheral circuit for the memory cell array 210. The peripheral circuit may perform a program, read, or erase operation of the memory cell array 210. The control circuit 220 may control the peripheral circuit.

The voltage generation circuit 230 may generate operation voltages of various levels. For example, in an erase operation, the voltage generation circuit 230 may generate operation voltages of various levels such as an erase voltage and a pass voltage.

The row decoder 240 may be in electrical communication with the voltage generation circuit 230, and the plurality of memory blocks 211. The row decoder 240 may select at least one memory block among the plurality of memory blocks 211 in response to a row address generated by the control circuit 220, and transmit operation voltages supplied from the voltage generation circuit 230 to the selected memory blocks.

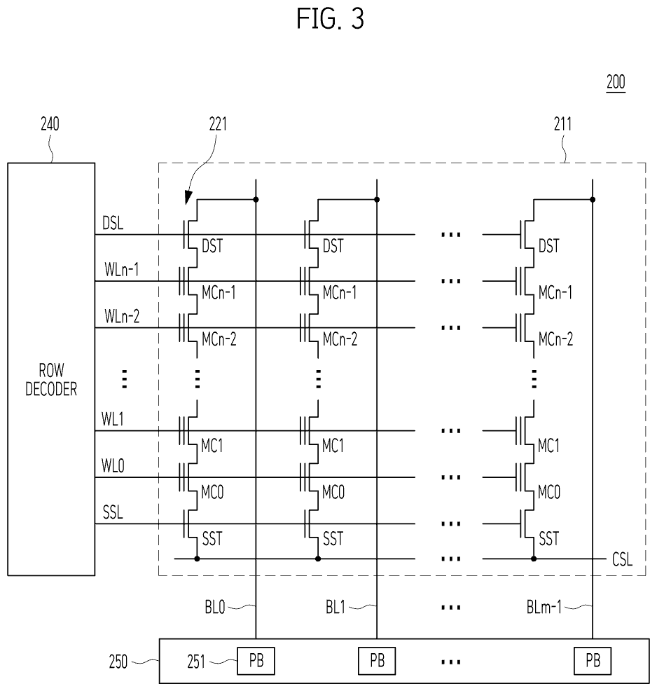

The page buffer 250 may be coupled with the memory cell array 210 through bit lines BL (shown in FIG. 3). The page buffer 250 may precharge the bit lines BL with a positive voltage, transmit data to, and receive data from, a selected memory block in program and read operations, or temporarily store transmitted data, in response to page buffer control signal(s) generated by the control circuit 220.

The column decoder 260 may transmit data to, and receive data from, the page buffer 250 or transmit and receive data to and from the input/output circuit 270.

The input/output circuit 270 may transmit to the control circuit 220 a command and an address, received from an external device (e.g., the memory controller 100 of FIG. 1), transmit data from the external device to the column decoder 260, or output data from the column decoder 260 to the external device, through the input/output circuit 270.

The control circuit 220 may control the peripheral circuit in response to the command and the address.

FIG. 3 is a circuit diagram illustrating a memory block of a semiconductor memory device in accordance with still another embodiment of the present invention. For example, the memory block of FIG. 3 may be any of the memory blocks 211 of the memory cell array 210 shown in FIG. 2.

Referring to FIG. 3, the exemplary memory block 211 may include a plurality of word lines WL0 to WLn−1, a drain select line DSL and a source select line SSL coupled to the row decoder 240. These lines may be arranged in parallel, with the plurality of word lines between the DSL and SSL.

The exemplary memory block 211 may further include a plurality of cell strings 221 respectively coupled to bit lines BL0 to BLm−1. The cell string of each column may include one or more drain selection transistors DST and one or more source selection transistors SST. In the illustrated embodiment, each cell string has one DST and one SST. In a cell string, a plurality of memory cells or memory cell transistors MC0 to MCn−1 may be serially coupled between the selection transistors DST and SST. Each of the memory cells may be formed as a multiple level cell. For example, each of the memory cells may be formed as a single level cell (SLC) storing 1 bit of data. Each of the memory cells may be formed as a multi-level cell (MLC) storing 2 bits of data. Each of the memory cells may be formed as a triple-level cell (TLC) storing 3 bits of data. Each of the memory cells may be formed as a quadruple-level cell (QLC) storing 4 bits of data.

The source of the SST in each cell string may be coupled to a common source line CSL, and the drain of each DST may be coupled to the corresponding bit line. Gates of the SSTs in the cell strings may be coupled to the SSL, and gates of the DSTs in the cell strings may be coupled to the DSL. Gates of the memory cells across the cell strings may be coupled to respective word lines. That is, the gates of memory cells MC0 are coupled to corresponding word line WL0, the gates of memory cells MC1 are coupled to corresponding word line WL1, etc. The group of memory cells coupled to a particular word line may be referred to as a physical page. Therefore, the number of physical pages in the memory block 211 may correspond to the number of word lines.

The page buffer array 250 may include a plurality of page buffers 251 that are coupled to the bit lines BL0 to BLm−1. The page buffers 251 may operate in response to page buffer control signals. For example, the page buffers 251 my temporarily store data received through the bit lines BL0 to BLm−1 or sense voltages or currents of the bit lines during a read or verify operation.

In some embodiments, the memory blocks 211 may include a NAND-type flash memory cell. However, the memory blocks 211 are not limited to such cell type, but may include NOR-type flash memory cell(s). Memory cell array 210 may be implemented as a hybrid flash memory in which two or more types of memory cells are combined, or one-NAND flash memory in which a controller is embedded inside a memory chip.

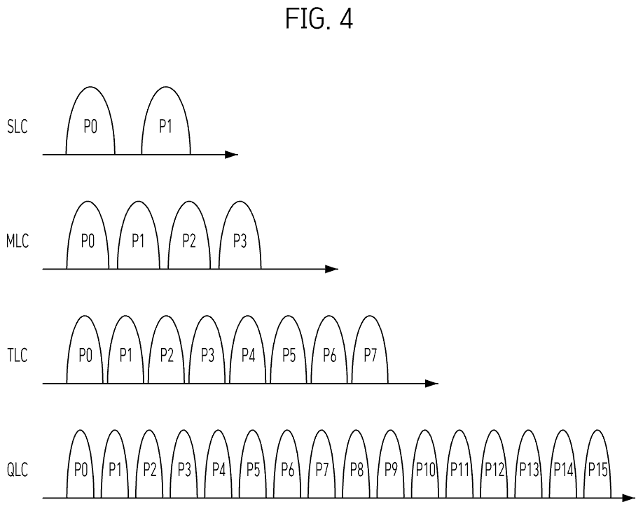

FIG. 4 is a diagram illustrating distributions of states or program voltage (PV) levels for different types of cells of a memory device.

Referring to FIG. 4, each of memory cells may be implemented with a specific type of cell, for example, a single level cell (SLC) storing 1 bit of data, a multi-level cell (MLC) storing 2 bits of data, a triple-level cell (TLC) storing 3 bits of data, or a quadruple-level cell (QLC) storing 4 bits of data. Usually, all memory cells in a particular memory device are of the same type, but that is not a requirement.

An SLC may include two states P0 and P1. P0 may indicate an erase state, and P1 may indicate a program state. Since the SLC can be set in one of two different states, each SLC may program or store 1 bit according to a set coding method. An MLC may include four states P0, P1, P2 and P3. Among these states, P0 may indicate an erase state, and P1 to P3 may indicate program states. Since the MLC can be set in one of four different states, each MLC may program or store two bits according to a set coding method. A TLC may include eight states P0 to P7. Among these states, P0 may indicate an erase state, and P1 to P7 may indicate program states. Since the TLC can be set in one of eight different states, each TLC may program or store three bits according to a set coding method. A QLC may include 16 states P0 to P15. Among these states, P0 may indicate an erase state, and P1 to P15 may indicate program states. Since the QLC can be set in one of sixteen different states, each QLC may program or store four bits according to a set coding method.

Referring back to FIGS. 2 and 3, the memory device 200 may include a plurality of memory cells (e.g., NAND flash memory cells). The memory cells are arranged in an array of rows and columns as shown in FIG. 3. The cells in each row are connected to a word line (e.g., WL0), while the cells in each column are coupled to a bit line (e.g., BL0). These word and bit lines are used for read and write operations. During a write operation, the data to be written (‘1’ or ‘0’) is provided at the bit line while the word line is asserted. During a read operation, the word line is again asserted, and the threshold voltage of each cell can then be acquired from the bit line. Multiple pages may share the memory cells that belong to (i.e., are coupled to) the same word line. When the memory cells are implemented with MLCs, the multiple pages include a most significant bit (MSB) page and a least significant bit (LSB) page. When the memory cells are implemented with TLCs, the multiple pages include an MSB page, a center significant bit (CSB) page and an LSB page. When the memory cells are implemented with QLCs, the multiple pages include an MSB page, a center most significant bit (CMSB) page, a center least significant bit (CLSB) page and an LSB page. The memory cells may be programmed using a coding scheme (e.g., Gray coding) in order to increase the capacity of the memory system 10 such as SSD.

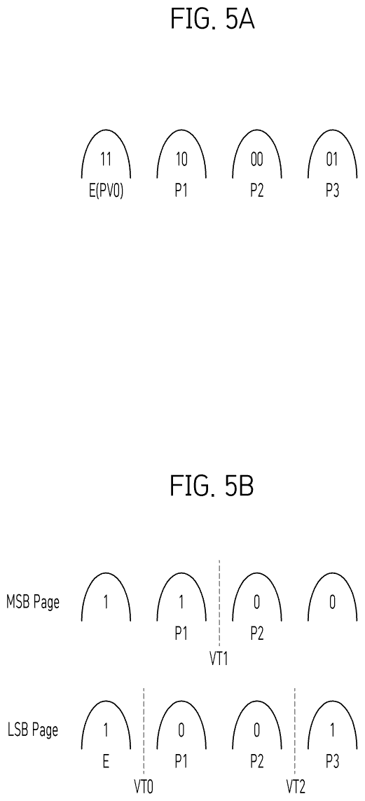

FIG. 5A is a diagram illustrating an example of coding for a multi-level cell (MLC).

Referring to FIG. 5A, an MLC may be programmed using a set coding. An MLC may have 4 program states, which include an erased state E (or PV0) and a first program state PV1 to a third program state PV3. The erased state E (or PV0) may correspond to “11.” The first program state PV1 may correspond to “10.” The second program state PV2 may correspond to “00.” The third program state PV3 may correspond to “01.”

In the MLC, as shown in FIG. 5B, there are 2 types of pages including LSB and MSB pages. 1 or 2 thresholds may be applied in order to retrieve data from the MLC. For an MSB page, the single threshold value is VT1. VT1 distinguishes between the first program state PV1 and the second program state PV2. For an LSB page, 2 thresholds include a threshold value VT0 and a threshold value VT2. VT0 distinguishes between the erased state E and the first program state PV1. VT2 distinguishes between the second program state PV2 and the third program state PV3.

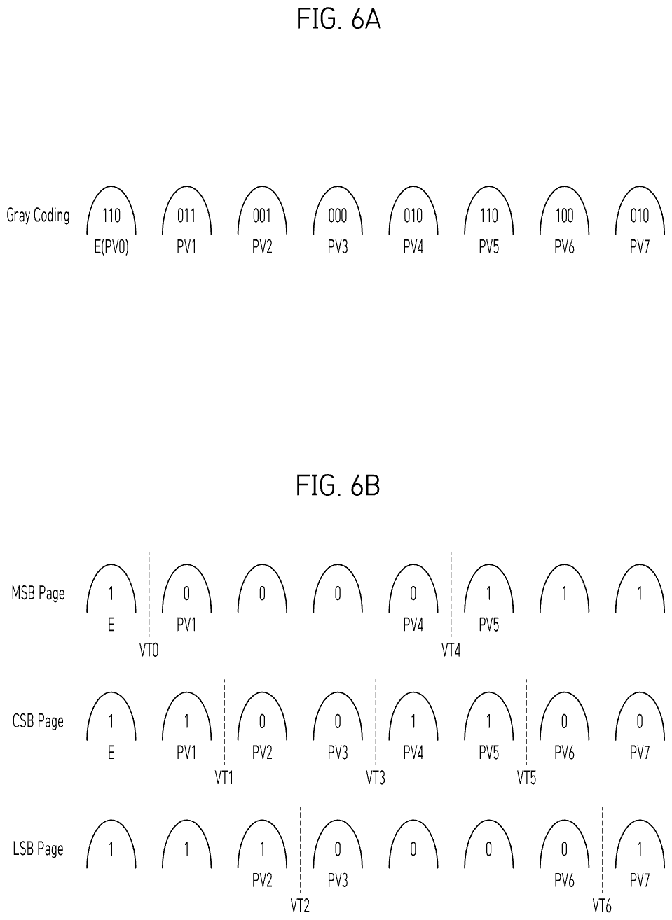

FIG. 6A is a diagram illustrating an example of Gray coding for a triple-level cell (TLC).

Referring to FIG. 6A, a TLC may be programmed using Gray coding. A TLC may have 8 program states, which include an erased state E (or PV0) and a first program state PV1 to a seventh program state PV7. The erased state E (or PV0) may correspond to “110.” The first program state PV1 may correspond to “011.” The second program state PV2 may correspond to “001.” The third program state PV3 may correspond to “000.” The fourth program state PV4 may correspond to “010.” The fifth program state PV5 may correspond to “110.” The sixth program state PV6 may correspond to “100.” The seventh program state PV7 may correspond to “101.”

In the TLC, as shown in FIG. 6B, there are 3 types of pages including LSB, CSB and MSB pages. 2 or 3 thresholds may be applied in order to retrieve data from the TLC. For an MSB page, 2 thresholds include a threshold value VT0 that distinguishes between an erase state E and a first program state PV1 and a threshold value VT4 that distinguishes between a fourth program state PV4 and a fifth program state PV5. For a CSB page, 3 thresholds include VT1, VT3 and VT5. VT1 distinguishes between a first program state PV1 and a second program state PV2. VT3 distinguishes between a third program state PV3 and the fourth program state PV4. VT5 distinguishes between the fourth program state PV5 and the sixth program state PV6. For an LSB page, 2 thresholds include VT2 and VT6. VT2 distinguishes between the second program state PV2 and the third program state PV3. VT6 distinguishes between the sixth program state PV6 and a seventh program state PV7.

After a memory array including a plurality of memory cells is programmed as described in FIGS. 5A and 6A, when a read operation is performed on the memory array using a certain voltage reference value such as a read threshold (i.e., read voltage level), the electrical charge levels of the memory cells (e.g., threshold voltage levels of transistors of memory cells) are compared to one or more voltage reference values (also called “read voltage level” or “read threshold”) to determine the state of individual memory cells. When a certain read threshold is applied to the memory array, those memory cells that have threshold voltage levels higher than the certain voltage reference value are turned on and detected as “on” cell, whereas those memory cells that have threshold voltage levels lower than the certain voltage reference value are turned off and detected as “off” cell, for example. Therefore, each read threshold is arranged between neighboring threshold voltage distribution windows corresponding to different programmed states so that each read threshold can distinguish such programmed states by turning on or off the memory cell transistors.

When a read operation is performed on memory cells in a data storage device using MLC technology, the threshold voltage levels of the memory cells are compared to more than one read threshold level to determine the state of individual memory cells. Read errors can be caused by distorted or overlapped threshold voltage distribution. An ideal memory cell threshold voltage distribution can be significantly distorted or overlapped due to, e.g., program and erase (P/E) cycle, cell-to-cell interference, and data retention errors. For example, as program/erase cycles increase, the margin between neighboring threshold voltage distributions of different programmed states decreases and eventually the distributions start overlapping. As a result, the memory cells with threshold voltages that fall within the overlapping range of the neighboring distributions may be read as being programmed to a value other than the original targeted value and thus cause read errors. Such read errors may be managed in most situations by using error correction codes (ECC). When the number of bit errors on a read operation exceeds the ECC correction capability of the data storage, the read operation fails.

Certain circumstances or operation conditions, such as charge leakage over time and device usage wear, can cause threshold voltages shift. Such a threshold voltage shift can produce read errors because several “off” cells may result in a threshold voltage higher than the read threshold due to the threshold voltage shift. Various circumstances can cause the threshold voltage shift to produce read errors. For example, memory devices with low endurance can produce more read errors than those with high endurance. Such a threshold voltage shift can be induced by operating conditions such as increased number of program/erase cycles of the memory array and increased operating temperature of the data storage devices. A read disturbance and the location of a memory chip or memory block may also be considered to determine whether the threshold voltage shift is likely to occur.

The endurance of a flash memory may indicate the maximum number of program/erase operations that the flash memory is able to perform successfully. Each memory cell can only be programmed and erased a limited number of times, before it becomes potentially unusable. In some embodiments, the endurance of a flash memory indicates the maximum number of program/erase operations per set period, e.g., day. The endurance of the flash memories can be affected by structural issues such as high memory densities and operating conditions such as high program voltages.

Data retention may refer to an operating condition relating to how long memory cells maintain a correct programmed state. Data retention can vary depending on the operating temperature and the number of program/erase cycles performed on the memory cells. Subjecting memory cells subject to high temperature and a large number of program/erase operations tends to lower their data retention.

The read disturbance indicates a phenomenon where reading data from a flash cell can cause the threshold voltages of other unread cells in the same block to shift to a different (e.g., higher) value. While a single threshold voltage shift is small, when read operations are performed over time, the threshold voltage shift eventually becomes large enough to alter the states of the memory cells.

Die, block and word line indices can represent the physical location of the memory cell to be read. A data storage device can be made up of a plurality of memory chip dies, each including a plurality of memory blocks. Each memory block includes a plurality of memory cells, and each memory cell can be selected by a word line coupled thereto. A memory controller can be configured to track movement of data across the plurality of dies and the plurality of blocks. Based on the movement of data, the memory controller can determine how many program/erase operations a certain memory die or a certain memory block has performed. This information can be stored with reference to die indices, block indices, and word line indices to identify location(s) where program/erase operations is/are concentrated. The possibility of read errors would be higher when reading out data from any of those locations.

Such read errors, however, can be minimized by modifying the read thresholds. In some embodiments, the read thresholds may be modified based on operating conditions that contribute to the read errors in flash memory-based data storage SSD devices. These operating conditions include, but are not limited to, the endurance of a memory device, data retention, read disturbance, age of the associated storage device, operating temperature of the data storage device, and the location of the memory cell to be read, which can be indicated by die indices, block indices, and/or word line indices.

The performance (e.g., input/output operations per second and throughput) of a data storage device such as an SSD is heavily dependent on the read threshold setting (i.e., read voltage setting) applied when the first read operation is conducted. If the read threshold is not optimized, the performance may be degraded because such unoptimized read threshold voltages can cause read errors. The optimization of the read threshold voltages depends on certain operating conditions such as physical location of data, device endurance, data retention time, operating temperature, read disturbance, and age of device. However, it is unrealistic to manually consider all the possible combinations of different operating conditions to modify the read thresholds. It would be even more difficult to manually obtain an optimized read threshold if the operating conditions change often. Accordingly, it is desirable to provide a system and a method for optimizing read threshold values using deep learning. One implementation of deep learning is described in U.S. Pat. No. 11,610,116 B2 issued on Mar. 21, 2023, entitled “STORAGE DEVICE PERFORMANCE OPTIMIZATION USING DEEP LEARNING” and incorporated by reference herein.

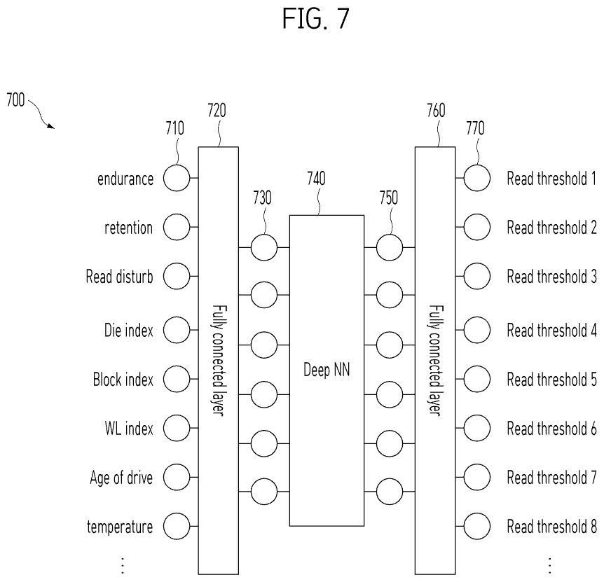

FIG. 7 illustrates an example of a deep neural network architecture for data storage performance optimization implemented based on some embodiments of the disclosed technology. The deep neural network architecture 700 for data storage performance optimization (including voltage threshold estimation) includes a plurality of input nodes 710, first and second connection layers 720 and 760, a plurality of connection nodes 730 and 750, and a deep neural network 740, and a plurality of output nodes 770. Here, the first and second connection layers 720 and 760 may be fully connected layers. For example, the first connection layer 720 may be configured to connect all the input nodes 710 to all the connection nodes 730 of the deep neural network 740. Likewise, the second connection layer 760 may be configured to connect all the output nodes 770 to all the connection nodes 750 of the deep neural network 740. In some embodiments of the disclosed technology, the input and output nodes 710 and may be input neurons and output neurons, and the first and second connection layers 720 and 760 may be synapse layers, as will be discussed below.

The already-trained deep neural network 740, through the plurality of input nodes 710, the first connection layer 720, and the first connection nodes 730, receives the operating conditions that contribute to the read errors, such as endurance, retention, read disturbance, die index, block index, word line index, age of the data storage drive, and/or temperature. The deep neural network 740 measures data in the memory devices under combinations of operating conditions using a set of read thresholds (supplied by synthetic models of the present disclosure described below). For example, the deep neural network 740 may read out data from a certain memory cell of the data storage device under the combination of the operating conditions, including the endurance of the memory device the certain memory cell belongs to, the data retention of the memory device the certain memory cell belongs to, an expected read disturbance associated with the certain memory cell, the age of the data storage, the operating temperature of the data storage, and the physical location of the certain memory cell, which can be determined based on the die index, the block index, and the word line index. In an implementation, the thresholds voltages optimized corresponding to each combination of operating conditions (or determined using the synthetic models described below) may be stored in a memory (e.g., SRAM) of the storage device.

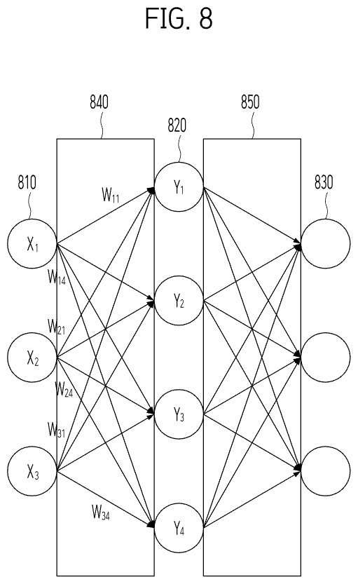

FIG. 8 illustrates an example configuration of a computational neural network including input neurons 810, hidden neurons 820, output neurons 830, and synapse layers 840 and 850. For example, the synapse layer 840 may include a plurality of weights W₁₁, W₁₂, W₁₃, W₁₄, W₂₁, W₂₂, W₂₃, W₂₄, W₃₁, W₃₂, W₃₃, and W₃₄. The input neurons 810 receive some values and propagate them to the hidden neurons 820 of the network. The weighted sums from one or more layers of hidden neurons 820 are ultimately propagated to the output neurons 830. Here, the outputs of the neurons are often referred to as activations, and the synapses are often referred to as weights. An example of the computation at each layer can be expressed as:

$$Yj = f ( {\sum }_{i = 1}^{3} W ij \times Xi + b ) \qquad ( Eq . 1 )$$

where Wji, Xi and Yj are the weights, input activations and output activations, respectively.

In some embodiments of the disclosed technology, input parameters such as endurance, retention, read disturbance, die index, block index, word line index, age of the data storage drive, and temperature are fed into the first layer of a deep neural network, and the outputs of that layer can be interpreted as representing the presence of different features that contribute to the threshold voltage shifts. At subsequent layers, these features are then combined into a measure of the likely presence of higher level features, which are further combined to provide a probability that these high-level features require read threshold or voltage threshold modifications.

In some embodiments of the disclosed technology, the neural network algorithm for data storage performance optimization includes determining the value of the weights (and bias) in the neural network and is referred to as training the network. Once trained, the program can perform its task by computing the output of the neural network using the weights determined during the training process. Running the program with these weights is referred to as inference.

### Synthetic Models for PV Distribution

In various embodiments of the present disclosure, the read errors can be minimized by using a deep neural network to calculate voltage thresholds (as the memory device ages or is otherwise used) with synthetic models of the PV state distributions such that errors in reading data from the memory device can be reduced.

In the family of voltage threshold (Vt) optimization algorithms, or eBoost algorithms, in general, there is a tradeoff between accuracy and the number of test reads and latency. In one embodiment of the present disclosure, a deep learning based iterative Vt optimization scheme is provided which can integrate different eBoost algorithms into the same flow while providing flexibility between accuracy and latency. Different product lines, for example TLC and QLC, mobile, client and enterprise, can use the same scheme with minimum modification(s).

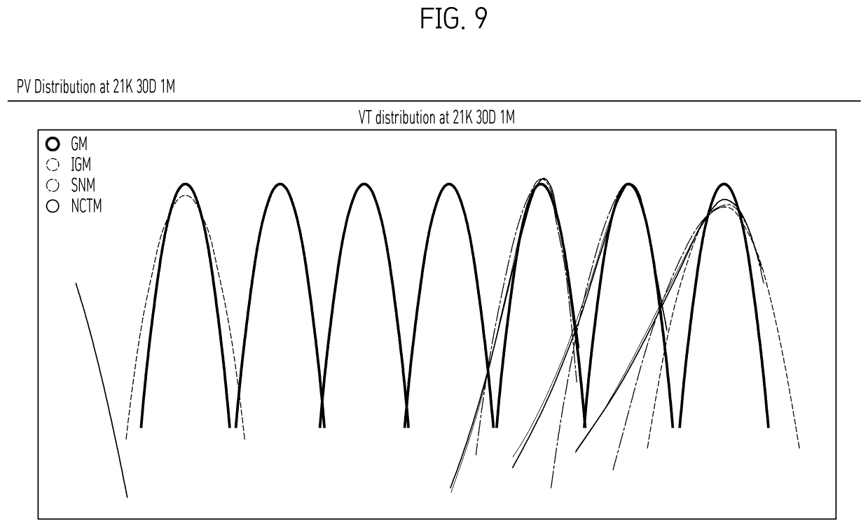

FIG. 9 is a graph depicting the PV distributions of the 20% worst WLs in a TLC after 21,000 program erase cycles (PEC) near end of life (EOL). The designation “30D 1M” on FIG. 9 refers to thirty (30) days of retention with one (1) million read disturbances. Four (4) different synthetic models are plotted on top of the PV distributions. In the Gaussian Model (GM), variance is assumed to be a constant and only the mean is a model variable to be estimated. Improved Gaussian Model (IGM) assumes both variance and mean are model parameters to be estimated. Skew Normal Model (SNM) has three (3) parameters (location, scale and shape) and non-central T model (NCTM) has four (4) parameters (degrees of freedom, non-centrality, location, shape). As evident, models with more parameters better approximate the underlying PV distribution with asymmetry and long tails.

### Model Parameter Estimate by Test Reads

In one embodiment of the present disclosure, in order to estimate the cross point of two adjacent PV distributions (which can be used to set reference voltages like the voltage threshold VT0, VT1, . . . VT6 shown in FIG. 6B), the model parameters of the left-side of one PV distribution and an adjacent right PV distribution are estimated by performing test reads using the PV distributions and with the established models (such as shown in FIG. 7) calculating the cross point(s). In theory, if the model has 1 unknown model parameter, 1 test read can estimate the unknown parameter. If the model has 2 unknown model parameters, in theory, 2 test reads can estimate the unknown parameters and so on.

In one embodiment of the present disclosure, a simple synthetic model (e.g., the GM) is used to estimate the Vt when its test reads are performed. If the read and decoding with the Vt estimated by simple synthetic model fails (that is a high error rate occurs in reading the data), a more complicated synthetic model (e.g., the IGM or SNM), which is more precise can be used, but requiring more test reads. In one embodiment of the present disclosure, the test reads for simple synthetic models can be reused by the more complicated synthetic models without re-performing the test reads that were already taken.

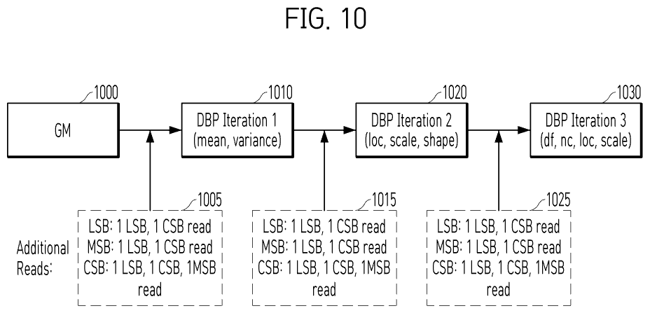

FIG. 10 shows one illustrative example of an iterative Vt estimation according to the present disclosure. At 1000, the GM engine model is established with its modeled PV distributions having an ideal Gaussian shape and voltage thresholds VT0, VT1, . . . VT6 like that shown in FIG. 6B. The modeled PV distributions may be obtained when the memory device is manufactured or relatively short time in use when the read disturbance effects noted above have not caused deviations. A test read using the voltage thresholds (VT0, VT1, . . . VT6) reads the LSB, MSB, and CSB pages of a memory to map out PV state counts by varying the read voltages across the entire range of the voltage thresholds with the values of the read voltages following the modeled PV distribution. (These first PV state counts obtained may be used to modify the original GM.) At 1005, the additional results of the first test read (i.e., the first PV state counts) are supplied to a DNN eBoost Pro (DBP) algorithm which in Iteration 1 uses a DNN to estimate the cross-point of left and right distribution(s) of an IGM engine model (with the mean and variance).

At 1010, DBP Iteration 1 occurs by a second read of the LSB, MSB, and CSB pages of a memory to map out second PV state counts by a second test read using the same voltage thresholds as before (VT0, VT1, . . . VT6) and by varying the read voltages across the entire range of the voltage thresholds with the values of the read voltages following the modified PV distribution produced by the IGM engine model. At 1015, the additional results of the second test read (i.e., the second PV state counts) are supplied to DBP Iteration 2 having the SNM engine model (with the location, scale, shape).

At 1020, DBP Iteration 2 occurs by a third read of the LSB, MSB, and CSB pages of a memory to map out third PV state counts by a third test read using the same voltage thresholds as before (VT0, VT1, . . . VT6) and by varying the read voltages across the entire range of the voltage thresholds with the values of the read voltages following the next modeled PV distribution produced by the SNM engine model. At 1025, the additional results of the third test read (i.e., the third PV state counts) are supplied to DBP Iteration 3 having the NCTM engine model (with the degrees of freedom, non-centrality, location, shape).

At 1030, DBP Iteration 3 occurs by a fourth read of the LSB, MSB, and CSB pages of a memory to map out fourth PV state counts by a fourth test read using the same voltage thresholds as before (VT0, VT1, . . . VT6) and by varying the read voltages across the entire range of the voltage thresholds with the values of the read voltages following the next modeled PV distribution produced by the NCTM engine model. At stages 1000, 1010, 1020, and 1030, the modeled PV distribution can be used to calculate new voltage thresholds (VT0′, VT1′, . . . VT6′).

In one particular embodiment, a DNN network engine in a system on chip (SoC) estimates the Vt. At different stages, different network weights can be loaded from DRAM into the DNN network engine in the SoC and perform the Vt estimate. A soft read and decoding operation is performed after each step. The process flow depicted in FIG. 8 can be modified for different memory products and meet different requirement. For example, in TLC products, the flow can be terminated after GM step. For QLC products, deeper stages can be used to ensure better reliability. The network weights used in different stages can be retrained based on different synthetic models, and no NAND data is needed during training.

In one embodiment, at stages like GM or iteration 1, a look-up-table instead of DNN can be used in the SoC. For stages deeper than iteration 1, a DNN is preferred because a high dimensional table with enough precision would consume memory.

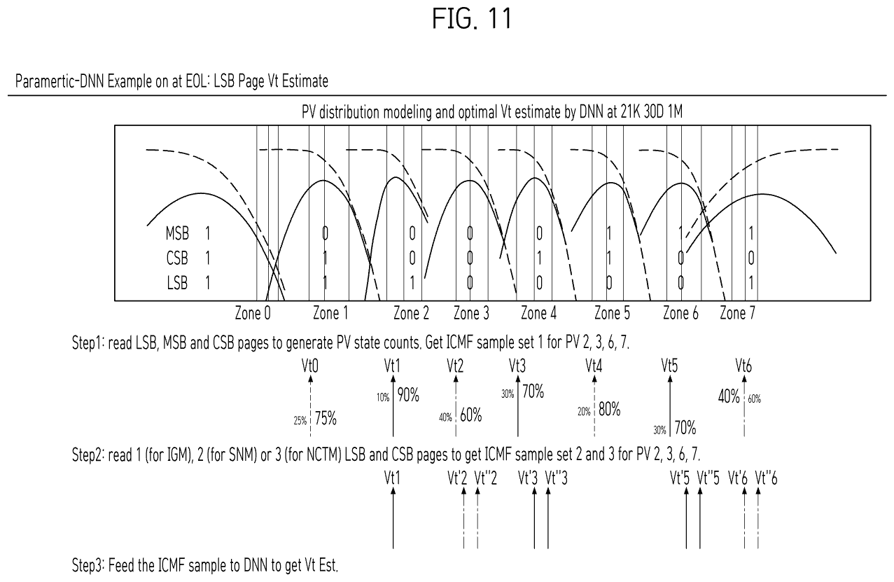

FIG. 11 shows the integration of GM, IGM, SNM and NCTM models into an iterative Vt estimation for an LSB page. At Step 1, the LSB, MSB, and CSB pages in a memory block are read (in the manner described above) to generate PV state counts. An ICMF sample set for PV zones 2, 3, 6, and 7 is obtained. Here, ICMF means the inverse of a cumulative mass function (CMF). In some embodiments, for each read threshold voltage, a cumulative mass function (CMF) value may be determined based on number of cells (cell count) and the number of a particular binary value (1 or 0) among the cells, which are associated with a read operation using each read threshold voltage. For example, each CMF value may be determined as {the number of 1's or 0's (e.g., 1's)/cell count}, i.e., the percentage of 1's or 0's.

The first ICMF sample set for PV 2,3,6,7 is shown in “Step 1” of FIG. 11. Samples for each page in the first ICMF sample set are generated from the parametric distributions at various read threshold voltages. In the illustrated example, for MSB pages, ICMF samples are generated at read threshold voltages Vt0, Vt4. The ICMF sample at the read threshold voltages Vt0 indicates a percentage 75% of 1's and a percentage 25% of 0's, and the ICMF sample at the read threshold voltages Vt4 indicates a percentage 80% of 1's and a percentage 20% of 0's. For CSB pages, ICMF samples are generated at read threshold voltages Vt1, Vt3, Vt5. The ICMF sample at the read threshold voltages Vt1 indicates a percentage 10% of 1's and a percentage 90% of 0's, the ICMF sample at the read threshold voltages Vt3 indicates a percentage 30% of 0's and a percentage 70% of 1's and the ICMF sample at the read threshold voltages Vt5 indicates a percentage 30% of 1's and a percentage 70% of 0's. For LSB pages, ICMF samples are generated at read threshold voltages Vt2, Vt6. The ICMF sample at the read threshold voltages Vt2 indicates a percentage 40% of 1's and a percentage 60% of 0's, and the ICMF sample at the read threshold voltages Vt6 indicates a percentage 40% of 0's and a percentage 60% of 1's.

At Step 2 of FIG. 11, the PV state counts for LSB and CSB of PV zone 1 to obtain the IGM shape of the PV state distribution for PV zone 1; the PV state counts for LSB and CSB of PV zone 2 is used to obtain the SNM shape of the PV state distribution for PV zone 2; and the PV state counts for LSB and CSB of PV zone 3 is used to obtain the NCTM shape of the PV state distribution for PV zone 3. From these reads, the ICMF is obtained for sample set 2 and 3 for PV zones 2, 3, 6, and 7.

At step 3 of FIG. 11, ICMF samples are sent to the neural network to obtain the Vt estimate.

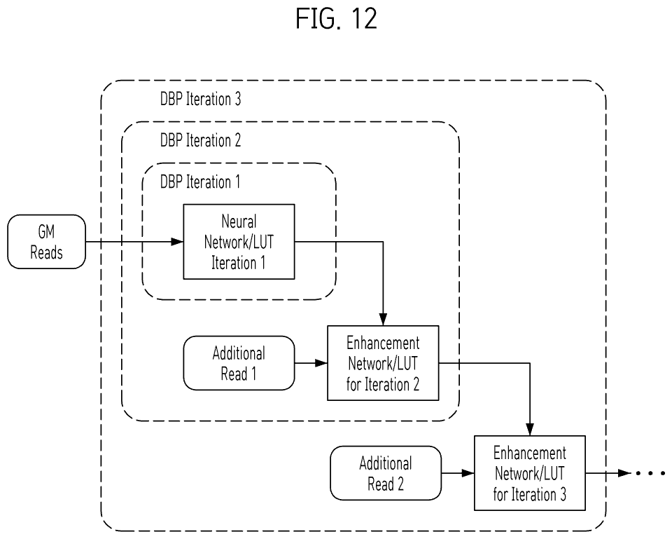

In one embodiment, if the neural network or lookup table for each iteration is separate, the SoC can store 3 separate networks/LUTs. Also, in one embodiment, the calculation of each iteration may start new with the GM reads and additional reads. In order to save memory consumption and reduce the inference latency through reusing previous iteration's result, the algorithm flow can be arranged as shown in FIG. 12.

In the nested arrangements shown in FIG. 12, in the DBP iteration 1, the GM reads are input into the network/LUT for DBP iteration 1, the output is saved. In DBP iteration 2, only the additional read and output from DBP iteration 1 is input into a first enhancement network/LUT (e.g., having one of the above noted IGM, SNM, or NCTM engines) to generate the output for DBP iteration 2. In DBP iteration 3, only the additional read and output from DBP iteration 2 is input into a second enhancement network/LUT (e.g., having the same or a more complicated engine models that the first enhancement network/LUT) to generate the output for DBP iteration 3. This process can be expanded to more stages. The memory size of 3 separate DBP network/LUTs is larger than the memory size of 1 DBP network/LUT and 2 enhancement network/LUTS. Since there are less weights in the weight-sharing design, the inference time should improve.

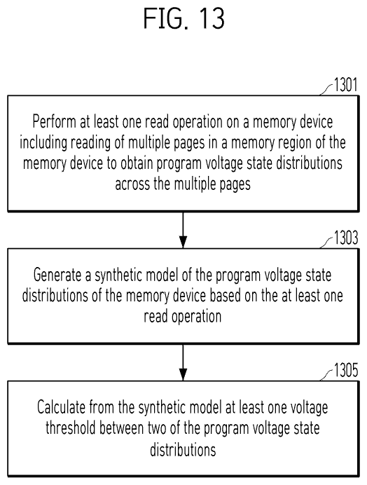

FIG. 13 is a flowchart illustrating a voltage threshold estimation operation in accordance with various embodiments of the present invention. The voltage threshold estimation operation may be performed by firmware of the controller 100 in FIG. 2 using the deep neural network 700 of FIG. 7. By way example and without any limitation, the voltage threshold estimation operation can be applied to LSB pages of TLC, as detailed in FIGS. 10 and 11. However, the voltage threshold estimation operation may be applied to other pages (i.e., MSB and CSB pages) of TLC, pages (i.e., MSB, LSB, CMSB and CLSB pages) of QLC or other types of NANDs consistent with the teachings herein.

Referring to FIG. 13, at 1301, controller 100 for example may perform at least one read operation on a memory device including reading of multiple pages (e.g., LSB, CSB, and MSB pages) in a memory region of the memory device to obtain program voltage state distributions across the multiple pages. At 1303, controller 100 for example may generate a synthetic model of the program voltage state distributions of the memory device based on the at least one read operation. At 1305, controller 100 for example may calculate from the synthetic model at least one voltage threshold between two of the program voltage state distributions. Although FIG. 13 is a flowchart, it represents the programing that would be embodied in a memory system having a) a memory device including multiple pages in a memory region and b) a controller coupled to the memory device and including this programming.

In one embodiment, the synthetic model utilized at least at 1303 may comprise at least one of a Gaussian Model (GM), an improved Gaussian Model (IGM), a Skew Normal Model (SNM), and non-central T model (NCTM). Further, the controller utilized at least at 1303 may vary the synthetic model between iterations which calculate from the synthetic model at least one voltage threshold between two of the program voltage state distributions. For example, a first iteration may utilize the GM, a second iteration may utilize the IGM, a third iteration may utilize the SNM, and a fourth iteration may utilize the NCTM.

In another embodiment, after at least one of the first, second, and third iterations, the at least one voltage threshold between two of the program voltage state distributions can be calculated, and error detection between each iteration may determine whether to perform at least one of the second, third, and fourth iterations. For example, after the first iteration, the controller utilized at least at 1303 may determine by a first error detection whether to perform the second iteration; after the second iteration, controller 100 may determine by a second error detection whether to perform the third iteration; and after the third iteration, the controller utilized at least at 1303 may determine by a third error detection whether to perform the third iteration. In other words, after at least one of the first, second, and third iterations, the controller utilized at least at 1303 may perform a subsequent read operation of the at least one read operation to provide input to a subsequent iteration.

In another embodiment, the controller utilized at least at 1303 for example may perform the at least one read operation on the multiple pages comprising reading a most significant bit (MSB) page, a center significant bit (CSB) page, and a least significant bit (LSB) page.

In another embodiment, the controller utilized at least at 1303 for example may generate with a neural network the synthetic model and calculate with the neural network the at least one voltage threshold between two of the program voltage state distributions.

In another embodiment, the controller utilized at least at 1303 for example may be provided with a look up table associating, for the synthetic model, data from the at least one read operation with a volage threshold value for at least one voltage threshold.

Although the foregoing embodiments have been illustrated and described in some detail for purposes of clarity and understanding, the present invention is not limited to the details provided. There are many alternative ways of implementing the invention, as one skilled in the art will appreciate in light of the foregoing disclosure. The disclosed embodiments are thus illustrative, not restrictive. The present invention is intended to embrace all modifications and alternatives that fall within the scope of the claims.

What is claimed is:

1. A memory system comprising:
a memory device including multiple pages in a memory region; and
a controller coupled to the memory device, and configured to:
perform at least one read operation on the memory device including reading of the multiple pages in the memory region of the memory device to obtain program voltage state distributions across the multiple pages;
generate a synthetic model of the program voltage state distributions of the memory device based on the at least one read operation; and
calculate from the synthetic model at least one voltage threshold between two of the program voltage state distributions.

2. The memory system of claim 1, wherein the synthetic model comprises at least one of a Gaussian Model (GM), an improved Gaussian Model (IGM), a Skew Normal Model (SNM), and non-central T model (NCTM).

3. The memory system of claim 2, wherein the controller is further configured to:
vary the synthetic model between iterations which calculate from the synthetic model at least one voltage threshold between two of the program voltage state distributions

4. The memory system of claim 3, wherein a first iteration utilizes the GM, a second iteration utilizes the IGM, a third iteration utilizes the SNM, and a fourth iteration utilizes the NCTM.

5. The memory system of claim 3, wherein
after at least one of the first, second, and third iterations, the at least one voltage threshold between two of the program voltage state distributions is calculated, and
error detection between each iteration determines whether to perform at least one of the second, third, and fourth iterations.

6. The memory system of claim 5, wherein
after the first iteration, a first error detection determines whether to perform the second iteration,
after the second iteration, a second error detection determines whether to perform the third iteration, and
after the third iteration, a third error detection determines whether to perform the fourth iteration.

7. The memory system of claim 3, wherein
after at least one of the first, second, and third iterations, a subsequent read operation of the at least one read operation is performed to provide input to a subsequent iteration.

8. The memory system of claim 1, wherein the multiple pages include a most significant bit (MSB) page, a center significant bit (CSB) page, and a least significant bit (LSB) page.

9. The memory system of claim 1, wherein the controller comprises a neural network which generates the synthetic model and calculates the at least one voltage threshold between two of the program voltage state distributions.

10. The memory system of claim 1, wherein the controller is programed with a look up table associating, for the synthetic model, data from the at least one read operation with a volage threshold value for the at least one voltage threshold.

11. A method for calculating a voltage threshold for reading data from a memory system including a memory device having multiple pages in a memory region and a controller coupled to the memory device, the method comprising:
performing at least one read operation on a memory device including reading of multiple pages in a memory region of the memory device to obtain program voltage state distributions across the multiple pages;
generating a synthetic model of the program voltage state distributions of the memory device based on the at least one read operation; and
calculating from the synthetic model at least one voltage threshold between two of the program voltage state distributions.

12. The method of claim 11, wherein the synthetic model comprises at least one of a Gaussian Mode (GM), an improved Gaussian Model (IGM), a Skew Normal Model (SNM), and non-central T model (NCTM) model.

13. The method of claim 11, further comprising:
varying the synthetic model between iterations which calculate from the synthetic model at least one voltage threshold between two of the program voltage state distributions.

14. The method of claim 13, wherein a first iteration utilizes the GM, a second iteration utilizes the IGM, a third iteration utilizes the SNM, and a fourth iteration utilizes the NCTM.

15. The method of claim 13, further comprising:
after at least one of the first, second, and third iterations, calculating the at least one voltage threshold between two of the program voltage state distributions, and
determining with error detection whether to perform at least one of the second, third, and fourth iterations.

16. The method of claim 15, further comprising:
after the first iteration, determining by a first error detection whether to perform the second iteration,
after the second iteration, determining by a second error detection whether to perform the third iteration, and
after the third iteration, determining by a third error detection whether to perform the fourth iteration.

17. The method of claim 13, further comprising:
after at least one of the first, second, and third iterations, a subsequent read operation of the at least one read operation to provide input to a subsequent iteration.

18. The method of claim 11, wherein the performing the at least one read operation on the multiple pages comprises reading a most significant bit (MSB) page, a center significant bit (CSB) page, and a least significant bit (LSB) page.

19. The method of claim 11, further comprising generating with a neural network in the controller the synthetic model and calculating with the neural network the at least one voltage threshold between two of the program voltage state distributions.

20. The method of claim 11, further comprising providing a look up table in the controller associating, for the synthetic model, data from the at least one read operation with a volage threshold value for the at least one voltage threshold.
